(19) United States
(12) Patent Application Publication
(10) Pub. No.: US 2026/0006916 A1
(43) Pub. Date: Jan. 1, 2026

(54) DISPLAY PANEL AND DISPLAY DEVICE

(71) Applicant: WUHAN CHINA STAR OPTOELECTRONICS TECHNOLOGY CO., LTD., Wuhan, Hubei (CN)

(72) Inventors: Peng HE, Wuhan, Hubei (CN); Wenkai ZHAO, Wuhan, Hubei (CN)

(73) Assignee: WUHAN CHINA STAR OPTOELECTRONICS TECHNOLOGY CO., LTD., Wuhan, Hubei (CN)

(21) Appl. No.: 18/834,134

(22) PCT Filed: Jul. 3, 2024
(86) PCT No.: PCT/CN2024/103341

§ 371 Date: Jul. 29, 2024

(30) Foreign Application Priority Data
Jun. 26, 2024 (CN) 202410842372.2

(51) Int. Cl. H10D 86/40; H01L 25/16; H10D 86/60; H10H 29/32; H10H 29/49; H10H 29/855

(52) U.S. Cl. CPC H10D 86/443; H01L 25/167; H10D 86/60; H10H 29/32; H10H 29/49; H10H 29/8552

(57) ABSTRACT

The present application provides a display panel and a display device. The display panel includes a driver circuit layer, a resistance reduction layer, and a light emitting device. The driver circuit layer includes a plurality of transistors. A first electrode, a second electrode, and a first power line are formed on the resistance reduction layer. The first electrode and the first power line are electrically connected to transistors. A first electrode member of the light emitting device is bonded to the first electrode, and a second electrode member of the light emitting device is bonded to the second electrode. A voltage uniformity on the first power line is greater than 85%.

### FIELD OF INVENTION

The present application relates to a field of display technologies, especially to a display panel and a display device.

### BACKGROUND OF INVENTION

With the development of display technologies, small interval light emitting diode (LED) direct displays have been gaining market share due to their excellent visual experience. For certain special high brightness scenarios, there is a demand to develop high-brightness (e.g., >20000 nit) and high brightness uniformity LED backplates. However, as the brightness and size of display panels increase, the impact of brightness uniformity due to voltage drop (IR drop) in power lines (such as VDD/VSS wiring) becomes significantly more pronounced. Therefore, reducing the voltage drop in power lines has become an urgent problem that needs to be addressed.

### SUMMARY OF INVENTION

The present application provides a display panel and a display device to lower a voltage drop of a power line.

Technical solutions provided by the present application are as follows:

In a first aspect, the embodiment of the present application provides a display panel, comprising:
an underlay substrate;
a driver circuit layer disposed on a side of the underlay substrate, wherein the driver circuit layer comprises a plurality of transistors;
a resistance reduction layer disposed on a side of the driver circuit layer away from the underlay substrate, wherein the resistance reduction layer are formed with a plurality of resistance reduction patterns, each of the resistance reduction patterns comprises a first electrode, a second electrode, and a first power line, the first electrode and the first power line are electrically connected to the transistors; and
light emitting devices disposed on a side of the resistance reduction layer away from the underlay substrate, wherein each of the light emitting devices comprises a first electrode member and a second electrode member, the first electrode member is bonded to the first electrode, and the second electrode member is bonded to the second electrode;
wherein a voltage uniformity on the first power line is greater than 85%.

In a second aspect, the embodiment of the present application provides a display device comprising the display panel of the above embodiment.

### DESCRIPTION OF DRAWINGS

To more clearly elaborate on the technical solutions of embodiments of the present invention or prior art, appended figures necessary for describing the embodiments of the present invention or prior art will be briefly introduced as follows. Apparently, the following appended figures are merely some embodiments of the present invention. A person of ordinary skill in the art may also acquire other figures according to the appended figures without any creative effort.

FIG. 1 is a schematic structural view of a film layer in a display panel of the related art.

FIG. 2 is a plane schematic structural view of a display panel provided by the embodiment of the present application.

FIG. 3 is a schematic structural view of a detailed portion of one display pixel in FIG. 2.

FIG. 4 is a schematic cross-sectional structural view along a N-N′ direction in FIG. 3.

FIG. 5 is a schematic structural view of the light emitting device bonded to the bonding electrode in the related art.

FIGS. 6a to 6e are schematic views of manufacturing flowcharts of the resistance reduction layer provided by the embodiment of the present application.

FIG. 7 is another partial film layer schematic structural view of the display panel provided by the embodiment of the present application.

FIG. 8 is still a partial film layer schematic structural view of the display panel provided by the embodiment of the present application.

FIG. 9 is still another partial film layer schematic structural view of the display panel provided by the embodiment of the present application.

FIG. 10 is a schematic view of an arrangement of resistance reduction patterns in adjacent two of the display pixels provided by the embodiment of the present application.

FIG. 11 is another plane schematic structural view of the display panel provided by the embodiment of the present application.

FIG. 12 is a plane schematic structural view of a motherboard provided by the embodiment of the present application.

FIG. 13 is a cross-sectional schematic structural view of the display device provided by the embodiment of the present application.

### DETAILED DESCRIPTION OF PREFERRED EMBODIMENTS

Each of the following embodiments is described with appending figures to illustrate specific embodiments of the present invention that are applicable. The terminologies of direction mentioned in the present invention, such as “upper”, “lower”, “front”, “rear”, “left”, “right”, “inner”, “outer”, “side surface”, etc., only refer to the directions of the appended figures. Therefore, the terminologies of direction are used for explanation and comprehension of the present invention, instead of limiting the present invention. In the figures, units with similar structures are marked with the same reference characters. In the accompanying drawings, for clear understanding and convenient descriptions, some thicknesses of layers and regions are exaggerated. Namely, a size and a size of each assembly in the accompanying drawings are illustrated arbitrarily, but the present application is not limited thereto.

To lower a voltage drop of a power line, the manufacturer usually disposes multiple metal layers in a display panel to form power lines in a large area. With reference to FIG. 1, FIG. 1 is a schematic structural view of a film layer in a display panel of the related art. The display panel comprises an underlay substrate 10′ and a driver circuit layer 20′, a first metal layer M1′, a second metal layer M2′, and a third metal layer M3′ that are sequentially disposed on the underlay substrate 10′. The third metal layer M3′ is configured to form a first electrode 31′ and a second electrode 32′. The first metal layer M1′ is configured to form a first power line 33′ with a large area. The second metal layer M2′ is configured to form a second power line 34′ with a large area. Utilizing multiple metal layers to form a first power line 33′ in a large area and a second power line 34′ in a large area can reduce the resistance of the first power line 33′ and the second power line 34′ to further reduce the voltage drop of the first power line 33′ and the second power line 34′.

However, the inventor(s) of the present application discovered during research that while setting multiple metal layers to form a large area power line can reduce the voltage drop of the power line and improve the voltage uniformity across different regions of the power line, for example, increasing the voltage uniformity to 65%, achieving higher voltage uniformity, for example, greater than 85%, is difficult to accomplish by merely setting multiple metal layers to form a large area power line. It should be explained that in the present application, the voltage uniformity of the power line is used as an indicator to measure the voltage drop across the power line. The smaller the voltage drop, the better the voltage uniformity of the power line. In particular, in the present application, the voltage uniformity of the power line refers to the ratio of voltages in different regions of the power line. For example, it can refer to the ratio of the voltage at the distal end of the power line to the voltage at the proximal end of the power line. The larger the ratio, the closer the voltage at the distal end is to the voltage at the proximal end, meaning the larger the ratio, the smaller the voltage drop along the power line, and correspondingly, the better the voltage uniformity of the power line. Herein, the proximal end of the power line refers to the region of the power line near the integrated circuit (IC), and the distal end of the power line refers to the region on the side of the power line away from the integrated circuit. The integrated circuit is connected to one end of the power line and is configured to provide a power voltage signal.

Therefore, through continuous research and exploration, the inventor(s) of the present application have proposed a display panel, motherboard, and display device to further reduce the voltage drop of the power line and achieve higher voltage uniformity.

In an embodiment, the embodiment of the present application provides a display panel, comprising:
an underlay substrate;
a driver circuit layer disposed on a side of the underlay substrate, wherein the driver circuit layer comprises a plurality of transistors;
a resistance reduction layer disposed on a side of the driver circuit layer away from the underlay substrate, wherein the resistance reduction layer are formed with a plurality of resistance reduction patterns, each of the resistance reduction patterns comprises a first electrode, a second electrode, and a first power line, the first electrode and the first power line are electrically connected to the transistors; and
light emitting devices disposed on a side of the resistance reduction layer away from the underlay substrate, wherein each of the light emitting devices comprises a first electrode member and a second electrode member, the first electrode member is bonded to the first electrode, and the second electrode member is bonded to the second electrode;
wherein a voltage uniformity on the first power line is greater than 85%.

In an embodiment, the resistance reduction pattern further comprises a second power line disposed opposite to and spaced from the first power line, a voltage uniformity of the second power line is greater than 85%, and the second power line and the second electrode are disposed integrally.

In an embodiment, material of the resistance reduction layer comprises copper, and a thickness of the resistance reduction layer ranges from 2 microns to 15 microns.

In an embodiment, the resistance reduction layer comprises a first copper layer and a second copper layer, the second copper layer is located on a side of the first copper layer away from the driver circuit layer, and a thickness of the second copper layer is greater than a thickness of the first copper layer.

In an embodiment, a boundary of the second copper layer extends beyond a boundary of the first copper layer.

In an embodiment, the display panel further comprises a first planarization layer located between the driver circuit layer and the resistance reduction layer, a first via hole is defined in the first planarization layer, and the first electrode is connected to the transistor through the first via hole in the first planarization layer.

In an embodiment, the display panel further comprises:
a first planarization layer disposed between the driver circuit layer and the resistance reduction layer;
a first metal layer disposed on a side of the first planarization layer away from the resistance reduction layer, wherein the first metal layer comprises an auxiliary electrode, and the first electrode is connected to the auxiliary electrode through a second via hole in the first planarization layer; and
a second planarization layer disposed on a side of the first metal layer away from the resistance reduction layer, wherein the auxiliary electrode is connected to the transistor through a third via hole in the second planarization layer.

In an embodiment, a first gap is formed between adjacent ones of the resistance reduction patterns, the display panel further comprises a filling structure disposed in the first gap, and along a direction perpendicular to the underlay substrate, an absolute value of a difference between a thickness of the filling structure and a thickness of the resistance reduction pattern is less than or equal to 1.5 microns.

In an embodiment, the display panel further comprises:
a first filling layer comprising a first filling portion disposed in the first gap; and
a first anti-reflective layer disposed on a side of the resistance reduction layer away from the driver circuit layer, wherein apertures are formed in portions of the first anti-reflective layer corresponding to the first electrode and the second electrode; wherein the first anti-reflective layer comprises a first anti-reflective portion covering the resistance reduction patterns and a second anti-reflective portion covering the first filling portion, and the second anti-reflective portion and the first filling portion commonly constitute the filling structure.

In an embodiment, the display panel further comprises:
a second anti-reflective layer, wherein apertures are defined in portions of the second anti-reflective layer corresponding to the first electrode and the second electrode, the second anti-reflective layer comprises a third anti-reflective portion and a fourth anti-reflective portion, the third anti-reflective portion covers the resistance reduction patterns, and the fourth anti-reflective portion is located in the first gap; and
a second filling layer comprising a second filling portion disposed in the first gap, wherein the second filling portion covers the fourth anti-reflective portion, and the fourth anti-reflective portion and the second filling portion commonly constitute the filling structure.

In an embodiment, the display panel further comprises:
a second anti-reflective layer, wherein aperture are defined in portions of second anti-reflective layer corresponding to the first electrode and the second electrode, the second anti-reflective layer comprises a third anti-reflective portion and a fourth anti-reflective portion, the third anti-reflective portion covers the resistance reduction patterns, and the fourth anti-reflective portion is located in the first gap; and
a third anti-reflective layer comprising a fifth anti-reflective portion disposed in the first gap, wherein the fifth anti-reflective portion covers the fourth anti-reflective portion, and the fourth anti-reflective portion and the fifth anti-reflective portion commonly constitute the filling structure.

In an embodiment, the filling structure comprises a protrusion portion, the protrusion portion protrudes from a plane in which a top surface of the resistance reduction pattern is located; an included angle between a side surface of the protrusion portion near the first electrode and a top surface of the first electrode is less than 90 degrees; and/or, an included angle between a side surface of the protrusion portion near the second electrode and a top surface of the second electrode is less than 90 degrees.

In an embodiment, the display panel comprises a display region and a frame region located outside the display region, the display panel further comprises a plurality of display pixels arranged in an array in the display region, an interval between any adjacent two of the display pixels is the same, each of the display pixels comprises at least three subpixels, each of the subpixels comprises at least one of the transistors, and one of the first electrodes, one of the second electrodes, and one of the light emitting devices; and in adjacent two of the display pixels, a difference between area ratios of the resistance reduction patterns is less than 20%.

In an embodiment, the frame region comprises at least one bonding region, the resistance reduction pattern further comprises a bonding terminal and/or a fanout wiring located in the bonding region, and a difference between the area ratio of the resistance reduction pattern in a unit area of the bonding region and the area ratio of the resistance reduction pattern in each of the display pixels is less than 20%.

In an embodiment, the display panel further comprises a plurality of dummy pixels located in the frame region, and a difference between the area ratio of the resistance reduction pattern in the dummy pixels and the area ratio of the resistance reduction pattern in the display pixels is less than 20%.

In an embodiment, each of the display pixels further comprises a portion of the first power line and a portion of the second power line, in each of the display pixels, a first notch is defined in a side of the first power line near the second power line, the first electrode is located in the first notch, a second notch is defined in a side of the second power line near the first power line, and the second electrode is located in the second notch.

In an embodiment, the embodiment of the present application also provides a display device comprising the display panel of one of the above embodiments.

In the display panel and the display device provided by the present application, the display panel comprises an underlay substrate and a driver circuit layer, a resistance reduction layer, and a light emitting device that are sequentially disposed on the underlay substrate. The driver circuit layer comprises a plurality of transistors. The resistance reduction layer forms a plurality of resistance reduction patterns. The resistance reduction pattern comprises a first electrode, a second electrode, and a first power line. The first electrode and the first power line are electrically connected to the transistors. The light emitting device comprises a first electrode member and a second electrode member. The first electrode member is bonded to the first electrode. A voltage uniformity on the first power line is greater than 85%. The second electrode member is bonded to the second electrode. The present application, by using a resistance reduction layer to form the first electrode, second electrode, and first power line, can reduce the voltage drop of the first power line, making the voltage uniformity on the first power line greater than 85%. Additionally, the first electrode and second electrode formed using the resistance reduction layer can serve as bonding electrodes, which can be directly bonded to the electrodes of light-emitting devices. This eliminates the need to set an adhesion layer or other layers between the bonding electrodes and the electrodes of light-emitting devices to enhance the adhesion of the film layers. Thus, the film layer structure of the bonding electrodes can be simplified, and the process can be simplified.

The following is a detailed description of the display panel and display device of the present application, in conjunction with the accompanying drawings and specific embodiments.

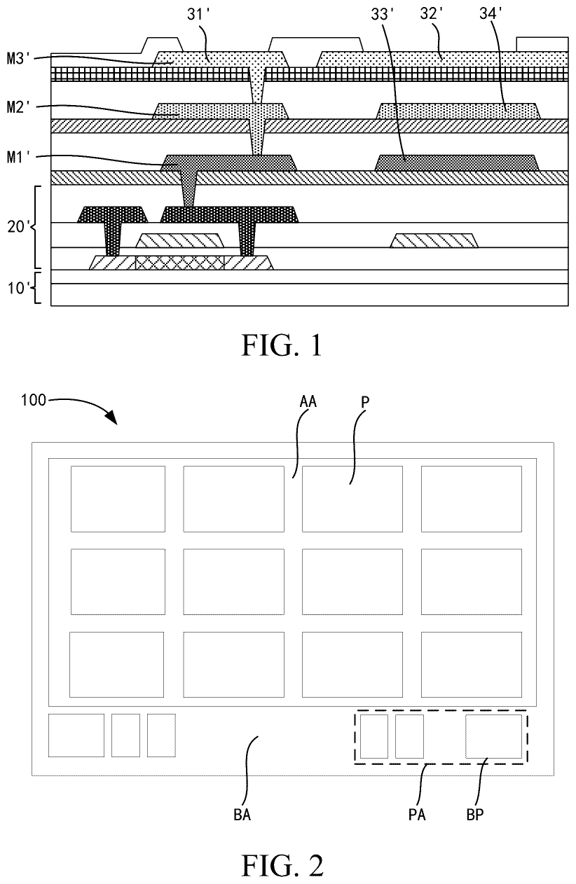

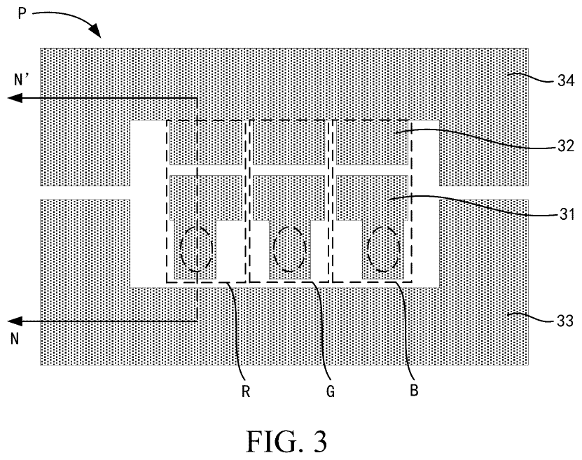

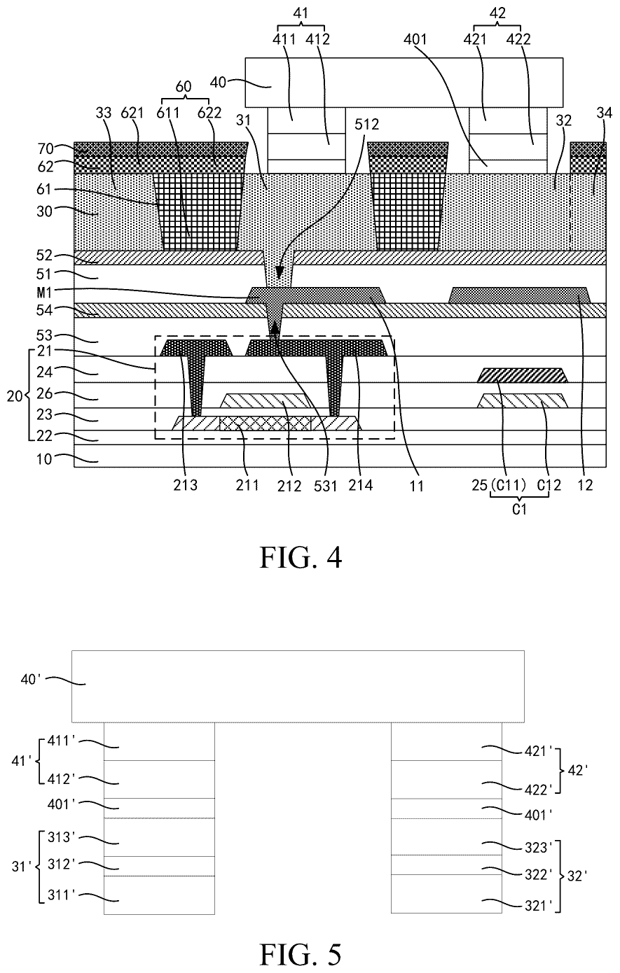

With reference to FIGS. 2 to 4, FIG. 2 is a plane schematic structural view of a display panel provided by the embodiment of the present application, FIG. 3 is a schematic structural view of a detailed portion of one display pixel in FIG. 2, FIG. 4 is a schematic cross-sectional structural view along a N-N′ direction in FIG. 3. With reference to FIG. 2, the display panel 100 comprises a display region AA and a frame region BA located outside the display region AA. The display region AA is configured to display images. The display region AA comprises a plurality of display pixels P arranged in an array. The frame region BA comprises at least one bonding region PA, a plurality of bonding terminals BP are disposed in the bonding region PA. An external circuit can implement bonding to the display panel 100 through the bonding terminals BP. The external circuit can comprise a driver integrated circuit (IC), a flexible wire board, etc.

With reference to FIG. 3, each of the display pixels P comprises at least three subpixels, for example, the three subpixels are a red subpixel R, a green subpixel G, and a blue subpixel B. The red subpixel R emits red light, the green subpixel G emits green light, and the blue subpixel B emits blue light to achieve color display of the display panel 100. Of course, three subpixels can also emit light of the same color, for example, the three subpixels emit blue light and cooperate with a quantum dot film and a color filter to achieve three base colors.

With reference to FIGS. 3 and 4, the display panel 100 further comprises underlay substrate 10 and a driver circuit layer 20, a resistance reduction layer 30, and a light emitting device 40 that are sequentially disposed on the underlay substrate 10. The driver circuit layer 20 is disposed on a side of the underlay substrate 10. The driver circuit layer 20 comprises a plurality of transistors 21. The resistance reduction layer 30 is disposed on a side of the driver circuit layer 20 away from the underlay substrate 10. A plurality of resistance reduction patterns are formed on the resistance reduction layer 30. The resistance reduction pattern comprises a first electrode 31, a second electrode 32, and a first power line 33. The first electrode 31 and the first power line 33 are electrically connected to the transistors 21. The light emitting device 40 is disposed on a side of the resistance reduction layer 30 away from the underlay substrate 10. The light emitting devices 40 comprises a first electrode member 41 and a second electrode member 42. The first electrode member 41 is bonded to the first electrode 31. The second electrode member 42 is bonded to the second electrode 32. A voltage uniformity of the first power line 33 is greater than 85%.

In the present embodiment, by using the resistance reduction layer 30 to form the first electrode 31, the second electrode 32, and the first power line 33, the voltage drop of the first power line 33 can be reduced, making the voltage uniformity of the first power line 33 greater than 85%. Additionally, using the resistance reduction layer 30 to form the first electrode 31 and the second electrode 32 as bonding electrodes allows direct bonding with the electrodes of the light-emitting devices 40, without the need for an adhesion layer to increase the adhesion between the upper and lower film layers between the bonding electrodes and the electrodes of the light-emitting devices 40. This simplifies the film layer structure of the bonding electrodes and the process.

The following will specifically explain the film layer structure of the display panel 100 and the structure of the resistance reduction layer 30 in conjunction with FIGS. 3 and 4.

With reference to FIG. 4, the display panel 100 comprises an underlay substrate 10. The underlay substrate 10 can be a rigid substrate or a flexible substrate. When the underlay substrate 10 is a rigid substrate, it can comprise a rigid substrate such as a glass substrate. When the underlay substrate 10 is a flexible substrate, it can comprise a flexible substrate such as a polyimide (PI) thin film, and a ultra-thin glass thin film.

The driver circuit layer 20 is disposed on the underlay substrate 10. The driver circuit layer 20 comprises at least one transistor 21. The transistor 21 can be a thin film transistor 21. The transistor 21 comprises an active layer 211, a gate electrode 212, source electrode 213, and a drain electrode 214. The active layer 211 comprises a channel region and a source region and a drain region located on two sides of the channel region. The gate electrode 212 is located on a side of the active layer 211 away from the underlay substrate 10. The gate electrode 212 is disposed to correspond to a channel region of the active layer 211. The source electrode 213 and the drain electrode 214 are located on a side of the gate electrode 212 away from the underlay substrate 10. The source electrode 213 is located on a source region of the active layer 211. The drain electrode 214 is connected to a drain region of the active layer 211. Of course, the structure of the transistor 21 of the present application is not limited, the transistor 21 in the present embodiment are only for illustration, and the transistor 21 of the present application can also adopt a framework such as a bottom gate or a dual-gate.

Furthermore, the driver circuit layer 20 further comprises insulation layers disposed among structures of the transistor 21. For example, the driver circuit layer 20 further comprises a buffer layer 22 disposed between the transistor 21 and the underlay substrate 10, a gate electrode insulation layer 23 disposed between the gate electrode 212 and the active layer 211, a first interlayer insulation layer 24 disposed between the gate electrode 212 and the source electrode 213 and the drain electrode 214. The source electrode 213 and the drain electrode 214 are connected respectively to the source region and the drain electrode 214 through via holes in the first interlayer insulation layer 24.

Optionally, the driver circuit layer 20 can further comprise a first capacitor C1. To form the first capacitor C1, the driver circuit layer 20 further comprises a conductive layer 25 and a second interlayer insulation layer 26 located between the first interlayer insulation layer 24 and the gate electrode 212. The conductive layer 25 is located on a side of the second interlayer insulation layer 26 away from the gate electrode 212. The conductive layer 25 forms a first electrode plate C11 of the first capacitor C1. A second electrode plate C12 of the first capacitor C1 and the gate electrode 212 are disposed in the same layer.

The resistance reduction layer 30 is disposed on a side of the driver circuit layer 20 away from the underlay substrate 10. A plurality of resistance reduction patterns are formed on the resistance reduction layer 30. The resistance reduction pattern comprises a first electrode 31, a second electrode 32, a first power line 33, and a second power line 34. The first electrode 31 and the first power line 33 are electrically connected to the transistor 21. For example, the first electrode 31 is electrically connected to the drain electrode 214 of the transistor 21. The first power line 33 is electrically connected to the source electrode 213 of the transistor 21.

The second power line 34 is opposite to and spaced from the first power line 33. a voltage uniformity of the second power line 34 is greater than 85%. The second electrode 32 is electrically connected to the second power line 34. Optionally, the second electrode 32 and the second power line 34 are disposed integrally. A gap is defined between the first electrode 31 and the second electrode 32 such that the first electrode 31 and the second electrode 32 are insulated from each other. A gap is defined between the first power line 33 and the second power line 34 such that the first power line 33 and the second power line 34 are insulated from each other. The first electrode 31 and the second electrode 32 are located between the first power line 33 and the second power line 34. Optionally, a first notch is defined in a side of the first power line 33 near the second power line 34. The first electrode 31 is located in the first notch. A second notch is defined in a side of the second power line 34 near the first power line 33. The second electrode 32 is located in the second notch. A voltage of the first power line 33 is greater than a voltage of the second power line 34, for example, the first power line 33 is VDD, and the second power line 34 is VSS.

Material of the resistance reduction layer 30 comprises copper, for example, the resistance reduction layer 30 is a thickness layer formed by a thick copper process. For example, a thickness of the resistance reduction layer 30 ranges from 2 microns to 15 microns. The thickness of the resistance reduction layer 30 is larger and has lower impedance. Thus, by using a thicker resistance reduction layer 30 to form the first power line 33, the impedance of the first power line 33 can be reduced, decreasing the voltage drop on the first power line 33, and ensuring that the voltage uniformity on the first power line 33 is greater than 85%, thereby improving the brightness uniformity of the display panel. Accordingly, by using a thicker resistance reduction layer 30 to form the second power line 34, the impedance of the second power line 34 can be reduced, decreasing the voltage drop on the second power line 34, ensuring that the voltage uniformity of the second power line 34 is greater than 85%, further improving the brightness uniformity of the display panel, thereby achieving higher brightness uniformity requirements.

The light emitting device 40 is disposed on a side of the resistance reduction layer 30 away from the driver circuit layer 20. The light emitting devices 40 comprises a first electrode member 41 and a second electrode member 42 disposed insulatively from each other. The first electrode member 41 is bonded to the first electrode 31. The second electrode member 42 is bonded to the second electrode 32. Optionally, the display panel 100 further comprises a soldering layer 401 located between the light emitting devices 40 and the resistance reduction layer 30. The first electrode member 41 and the second electrode member 42 are bonded to the first electrode 31 and the second electrode 32 respectively through corresponding portions of the soldering layer 401. Also, the first electrode 31 and the second electrode 32 contact the soldering layer 401. A solder of the soldering layer 401 can be a solder or a eutectic solder composed of tin and indium. One of the first electrode member 41 and the second electrode member 42 is an anode, and the other is a cathode. The first electrode member 41 comprises a first signal terminal 411 and a first gold layer 412 covering a surface of the first signal terminal 411. The second electrode member 42 comprises a second signal terminal 421 and a second gold layer 422 covering a surface of the second signal terminal 421.

By using the resistance reduction layer 30 to form the first electrode 31 and the second electrode 32, the resistance of the first electrode 31 and the second electrode 32 can be reduced. Furthermore, the first electrode 31 and the second electrode 32 are directly bonded with the light-emitting devices 40, which can reduce the contact resistance between the first electrode 31 and the second electrode 32 and the light-emitting devices 40. This can further reduce the voltage drop and improve the brightness uniformity of the display panel, thus achieving higher requirements for brightness uniformity. Additionally, using the resistance reduction layer 30 to form the first electrode 31 and the second electrode 32 and directly bonding with the light-emitting devices 40 can simplify the film layer structure of the bonding electrode and simplify the process.

In particular, with reference to FIG. 5, FIG. 5 is a schematic structural view of the light emitting device bonded to the bonding electrode in the related art. A first electrode member 41′ of a light emitting device 40′ is bonded to a first electrode 31′ through the soldering layer 401′, a second electrode member 42′ of the light emitting device 40′ is also bonded to a second electrode 32′ through the soldering layer 401′. The first electrode member 41′ comprises a first signal terminal 411′ and a first gold layer 412′ covering a surface of the first signal terminal 411′. The the second electrode member 42′ comprises a second signal terminal 421′ and a second gold layer 422′ covering a surface of the second signal terminal 421′. To improve the bonding stability of the first electrode member 41′ with the first electrode 31′ and the bonding stability of the second electrode member 42′ with the second electrode 32′, the first electrode 31′ and second electrode 32′ are usually disposed as a lamination layer with multiple metal layers. For example, the first electrode 31′ comprises a first terminal portion 311′, a first adhesion layer 312′, a first auxiliary copper layer 313′, and the second electrode 32′ comprises a second terminal portion 321′, a second adhesion layer 322′, and a second auxiliary copper layer 323′. Material of the first terminal portion 311′ and the second terminal portion 321′ is a titanium aluminum titanium metal lamination layer. Material of the first adhesion layer 312′ and the second adhesion layer 322′ is titanium. Material of the first auxiliary copper layer 313′ and the second auxiliary copper layer 323′ is copper. The present application adopts the resistance reduction layer 30 to form the first electrode 31 and the second electrode 32. Both the first electrode 31 and the second electrode 32 are directly in contact with the corresponding soldering layer 401 and are respectively bound directly with the first electrode member 41 and second electrode member 42 of the light emitting devices 40 through the corresponding soldering layer 401. Therefore, there is no need to set an adhesion layer and auxiliary copper layer between the bonding electrode and the electrode of the light emitting devices 40 to increase the adhesion of the upper and lower film layers. This simplifies the film layer structure of the bonding electrode and the process.

The following specifically describes the implementation method of electrically connecting the first electrode 31 of the present application with the transistor 21. With further reference to FIG. 4, the display panel 100 further comprises a first metal layer M1 located between the resistance reduction layer 30 and the driver circuit layer 20. The first metal layer M1 comprises an auxiliary electrode 11 and signal wiring 12. The signal wiring 12 can be any display signal wiring 12 for implementing a display function of the display panel 100. The first electrode 31 is electrically connected to the drain electrode 214 of the transistor 21 through the auxiliary electrode 11. Of course, the display panel 100 further comprises a plurality of insulation layers disposed among the first metal layer M1 and the resistance reduction layer 30 and the driver circuit layer 20. In particular, the insulation layer comprises a first planarization layer 51 and a first passivation layer 52 located between the first metal layer M1 and the resistance reduction layer 30, and a second planarization layer 53 and a second passivation layer 54 located between the first metal layer M1 and the driver circuit layer 20. The first passivation layer 52 is located on a side of the first planarization layer 51 away from the underlay substrate 10. The second passivation layer 54 is located on a side of the second planarization layer 53 away from the underlay substrate 10. Material of the first planarization layer 51 and the second planarization layer 53 comprises organic material such as organic photoresist. Material of the first passivation layer 52 and the second passivation layer 54 comprises inorganic material such as silicon oxide and silicon nitride.

The first electrode 31 is connected to the auxiliary electrode 11 through a second via hole 512 in the first planarization layer 51. The auxiliary electrode 11 is connected to the drain electrode 214 of the transistor 21 through a third via hole 531 in the second planarization layer 53 to achieve electrical connection of the first electrode 31 with the drain electrode 214 of the transistor 21.

In an embodiment, with further reference to FIG. 4, in order to improve the bonding yield of the light-emitting devices 40 with the first electrode 31 and the second electrode 32, it is necessary to enhance the flatness of the film layer in which the first electrode 31 and the second electrode 32 are located. However, the thickness of the resistance reduction layer 30 is relatively large, which causes the resistance reduction layer 30 to form deep pits between the resistance reduction patterns when the resistance reduction patterns are formed. The presence of these deep pits severely affects the flatness of the film layer, which in turn seriously impacts the bonding yield of the light-emitting devices 40 with the first electrode 31 and the second electrode 32. Therefore, in the embodiment of the present application, a filling structure 60 is provided between adjacent resistance reduction patterns to improve the flatness of the film layer.

In particular, a first gap is defined between adjacent ones of the resistance reduction patterns. The display panel 100 further comprises a filling structure 60 disposed in the first gap, along a direction perpendicular to the underlay substrate 10, an absolute value of a difference between a thickness of the filling structure 60 and a thickness of the resistance reduction pattern is less than or equal to 1.5 microns. For example, the absolute value of the difference between the thicknesses thereof is 1.5 microns, 1.4 microns, 1.3 microns, 1.2 microns, 1.1 microns, 1 microns, 0.9 microns, 0.8 microns, 0.7 microns, 0.6 microns, 0.5 microns, 0.4 microns, 0.3 microns, 0.2 microns, 0.1 microns, 0 microns, etc.

Optionally, the display panel 100 further comprises a first filling layer 61 and a first anti-reflective layer 62. The first filling layer 61 comprises a first filling portion 611 disposed in the first gap. The first anti-reflective layer 62 is disposed on a side of the resistance reduction layer 30 away from the driver circuit layer 20, and apertures are defined in portions of the first anti-reflective layer 62 corresponding to the first electrode 31 and the second electrode 32. The first anti-reflective layer 62 comprises a first anti-reflective portion 621 covering the resistance reduction patterns and a second anti-reflective portion 622 covering the first filling portion 611. For example, the first anti-reflective portion 621 covers surfaces of the first power line 33 and the second power line 34. The second anti-reflective portion 622 and the first filling portion 611 commonly constitute the filling structure 60. Material of the first filling layer 61 comprises organic photoresist such as OC. Material of the first anti-reflective layer 62 comprises organic photoresist such as BM or other material including an anti-reflection function. The first anti-reflective layer 62 functions to reduce the reflectivity of the metal surface. Therefore, by setting the first filling layer 61 and the first anti-reflective layer 62, it is possible to improve the flatness of the film layer, thereby increasing the bonding yield, while also reducing the surface reflectivity of the resistance reduction layer 30.

Optionally, the filling structure 60 comprises a protrusion portion. The protrusion portion protrudes from a plane in which a top surface of the resistance reduction pattern is located. For the present embodiment, the second anti-reflective portion 622 is the protrusion portion. An included angle between a side surface of the protrusion portion near the first electrode 31 and a top surface of the first electrode 31 is less than 90 degrees, namely, a bottom tangent structure is formed between the protrusion portion and the first electrode 31; and/or, an included angle between a side surface of the protrusion portion near the second electrode 32 and a top surface of the second electrode 32 is less than 90 degrees, namely, a bottom tangent structure is formed between the protrusion portion and the second electrode 32. By forming the filling structure 60 into a protrusion portion, the height of the protrusion portion is less than 1.5 microns, creating a shallow pit above the first electrode 31 and the second electrode 32. This helps block the flow of solder from the soldering layer 401 during the bonding process of the light emitting devices 40 with the first electrode 31 and the second electrode 32, thereby preventing short circuits between the first electrode 31 and the second electrode 32 and further improving the bonding yield. Additionally, by forming a bottom tangent structure between the protrusion portion and the first electrode 31 and/or the second electrode 32, the flow of solder from the soldering layer 401 can be further effectively blocked, preventing short circuits between the first electrode 31 and the second electrode 32 and further improving the bonding yield. Optionally, to facilitate the formation of a bottom tangent structure between the protrusion portion and the first electrode 31 and/or the second electrode 32, the material used to form the protrusion portion can be selected as negative photoresist.

Optionally, the display panel 100 further comprises a protective layer disposed on a side of the resistance reduction layer 30 away from the driver circuit layer 20. In particular, the protective layer is disposed on a side of the first anti-reflective layer 62 away from the resistance reduction layer 30, and the protective layer covers a surface of the first anti-reflective layer 62. Of course, apertures are also defined in portions of the protective layer corresponding to the first electrode 31 and the second electrode 32 to expose the first electrode 31 and the second electrode 32. Material of the protective layer includes inorganic materials such as silicon oxide and silicon nitride. The protective layer is configured to block water and oxygen to protect the metal wiring inside the display panel 100.

The following specifically explains how to form the resistance reduction layer 30:

Optionally, the resistance reduction layer 30 in the present application is prepared using an electroplating thick copper process. During continuous exploration and research, the inventor(s) of the present application discovered that to reduce the voltage drop of the power line, it is necessary to use a low-resistivity metal with relatively thick thickness. Common process solutions include physical vapor deposition (PVD), current body, screen printing, electroplating, chemical plating, evaporation, etc. Common metals include Al, Mo, Ag, Au, Cu, etc. However, considering issues such as stress-induced cracking, alignment accuracy, processing time, unsuitability for large sizes, and high costs, the electroplating thick copper solution was chosen as the optimal solution.

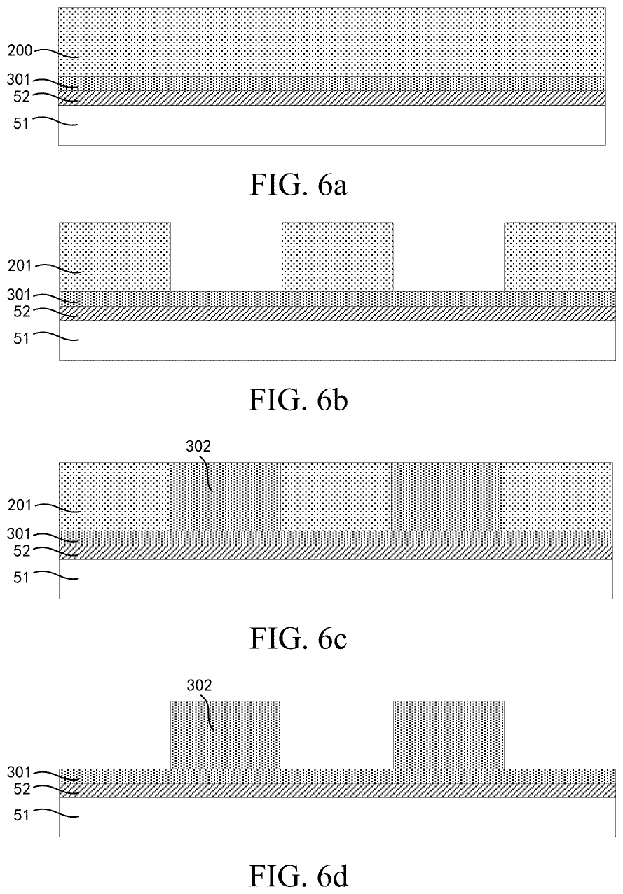

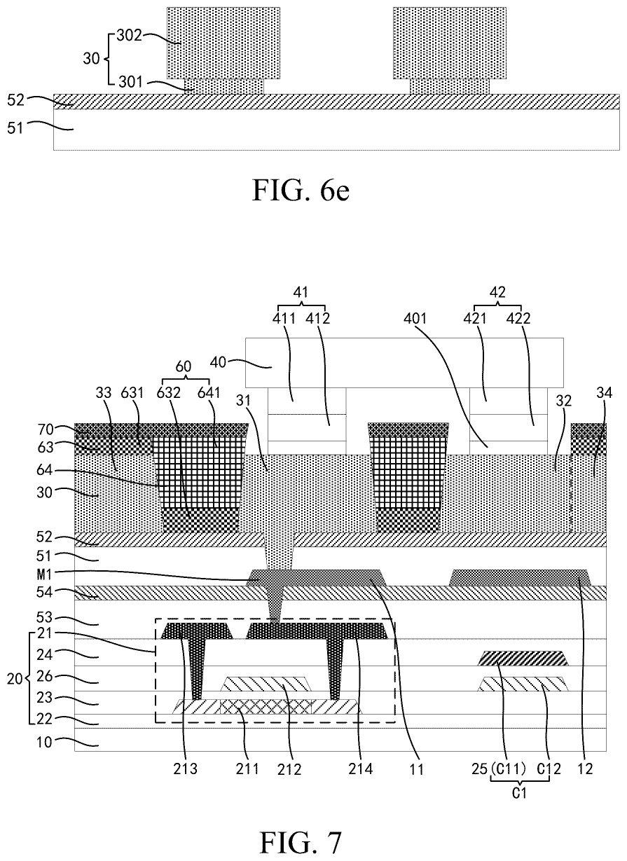

In particular, with reference to FIGS. 6a to 6e, FIGS. 6a to 6e are schematic views of the preparation process for the resistance reduction layer 30 provided by the embodiment of the present application. FIG. 6a is a schematic view of the preparation of the first copper layer 301 and photoresist layer 200 on the first passivation layer 52 provided by the embodiment of the present application. FIG. 6b is a schematic view of forming a photoresist pattern 201 in the photoresist layer 200 in FIG. 6a. FIG. 6c is a schematic view of electroplating a second copper layer 302 on the structure in FIG. 6b. FIG. 6d is a schematic view of removing the photoresist pattern 201 in FIG. 6c. FIG. 6e is a schematic view of etching the first copper layer 301 in FIG. 6d. With reference to FIG. 6a, Physical Vapor Deposition (PVD) is used to deposit the first copper layer 301 on the first passivation layer 52 as a seed copper layer. The material of the first copper layer 301 is copper. Next, a photoresist layer 200 is formed on the first copper layer 301. With reference to FIG. 6b, the photoresist layer 200 is exposed and developed to form a photoresist pattern 201, with a gap between adjacent photoresist patterns 201. With reference to FIG. 6c, a thick copper electroplating process is used to electroplate thick copper in the gap between the adjacent photoresist patterns 201 to form the second copper layer 302. The material of the second copper layer 302 is copper. With reference to FIG. 6d, the photoresist pattern 201 is removed to expose the first copper layer 301. With reference to FIG. 6e, the first copper layer 301 is etched to form the resistance reduction patterns of the resistance reduction layer 30. The resistance reduction layer 30 comprises a first copper layer 301 and a second copper layer 302. The second copper layer 302 is located on the side of the first copper layer 301 away from the driver circuit layer 20. The thickness of the second copper layer 302 is greater than the thickness of the first copper layer 301. Since the second copper layer 302 is formed using a low-resistance electroplating process, the density of the second copper layer 302 is greater than that of the first copper layer 301. Therefore, the second copper layer 302 is less prone to etching compared to the first copper layer 301. When etching the first copper layer 301, the boundary of the first copper layer 301 contracts inward relative to the boundary of the second copper layer 302, forming a bottom tangent structure, where the boundary of the second copper layer 302 extends beyond the boundary of the first copper layer 301.

In an embodiment, with reference to FIGS. 2 to 7, FIG. 7 is another partial film layer schematic structural view of the display panel 100 provided by the embodiment of the present application. With reference to FIG. 7, different from the above embodiment, the display panel 100 further comprises a second anti-reflective layer 63 and a second filling layer 64. Apertures are defined in portions of the second anti-reflective layer 63 corresponding to the first electrode 31 and the second electrode 32. The second anti-reflective layer 63 comprises a third anti-reflective portion 631 and a fourth anti-reflective portion 632. The third anti-reflective portion 631 covers the resistance reduction patterns. For example, the third anti-reflective portion 631 covers surfaces of the first power line 33 and the second power line 34. The fourth anti-reflective portion 632 is located in the first gap. The second filling layer 64 comprises a second filling portion 641 disposed in the first gap. The second filling portion 641 covers the fourth anti-reflective portion 632. The fourth anti-reflective portion 632 and the second filling portion 641 commonly constitute the filling structure 60. Material of the second filling layer 64 comprises organic photoresist such as OC. Material of the second anti-reflective layer 63 comprises a organic photoresist such as BM or other material comprising an anti-reflection function. The second anti-reflective layer 63 has a function of reducing a metal surface reflectivity. Thus, disposing the second filling layer 64 and the second anti-reflective layer 63 improves film layer flatness to further improve the bonding yield while lowering the surface reflectivity of the resistance reduction layer 30.

Optionally, the filling structure 60 comprises a protrusion portion, the protrusion portion protrudes from a plane in which a top surface of the resistance reduction pattern is located, for the present embodiment, the second filling portion 641 protrudes from a plane in which a top surface of the resistance reduction pattern is located, which namely is the protrusion portion. An included angle between a side surface of the protrusion portion near the first electrode 31 and a top surface of the first electrode 31 is less than 90 degrees. Namely, a bottom tangent structure is formed between the protrusion portion and the first electrode 31; and/or, an included angle between a side surface of the protrusion portion near the second electrode 32 and a top surface of the second electrode 32 is less than 90 degrees. Namely, a bottom tangent structure is formed between the protrusion portion and the second electrode 32. By forming the filling structure 60 with the protrusion portion, the height of the protrusion portion is less than 1.5 microns, creating a shallow pit above the first electrode 31 and the second electrode 32. This prevents the flow of solder from the soldering layer 401 during the binding process of the light-emitting devices 40 with the first electrode 31 and the second electrode 32, thereby avoiding a short circuit between the first electrode 31 and the second electrode 32 and further improving the bonding yield. Moreover, by forming a bottom tangent structure between the protrusion portion and the first electrode 31 and/or the second electrode 32, the flow of solder from the soldering layer 401 can be further effectively blocked, avoiding a short circuit between the first electrode 31 and the second electrode 32, thus further improving the bonding yield. Optionally, to facilitate the formation of a bottom tangent structure between the protrusion portion and the first electrode 31 and/or the second electrode 32, the material for the structure of the protrusion portion can be chosen as negative photoresist. For other descriptions, please refer to the above embodiment, and no repeated description is provided here.

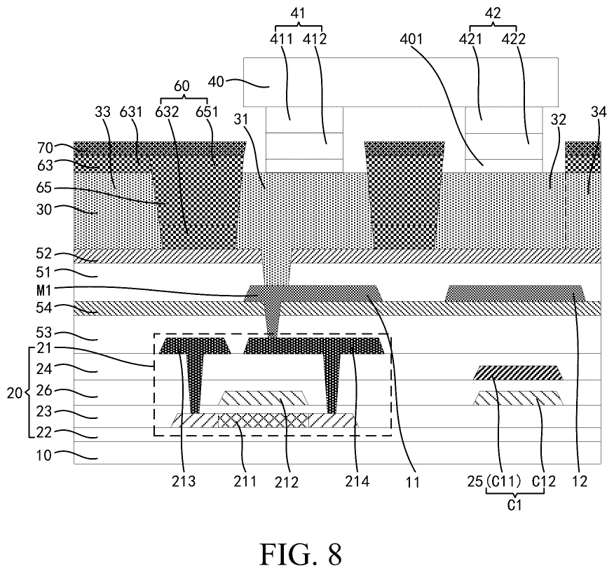

In an embodiment, with reference to FIGS. 2 to 8, FIG. 8 is still a partial film layer schematic structural view of the display panel 100 provided by the embodiment of the present application. With reference to FIG. 8, different from the above embodiment, the display panel 100 further comprises a second anti-reflective layer 63 and a third anti-reflective layer 65. Apertures are defined in portions of the second anti-reflective layer 63 corresponding to the first electrode 31 and the second electrode 32. The second anti-reflective layer 63 comprises a third anti-reflective portion 631 and a fourth anti-reflective portion 632. The third anti-reflective portion 631 covers the resistance reduction patterns. The fourth anti-reflective portion 632 is located in the first gap. The third anti-reflective layer 65 comprises a fifth anti-reflective portion 651 disposed in the first gap. The fifth anti-reflective portion 651 covers the fourth anti-reflective portion 632. The fourth anti-reflective portion 632 and the fifth anti-reflective portion 651 commonly constitute the filling structure 60. Material of the third anti-reflective layer 65 comprises an organic photoresist such as BM or other material with an anti-reflection function. The third anti-reflective layer 65 comprises a function of reducing a metal surface reflectivity. For other descriptions please refer to the above embodiment, and no repeated description is here.

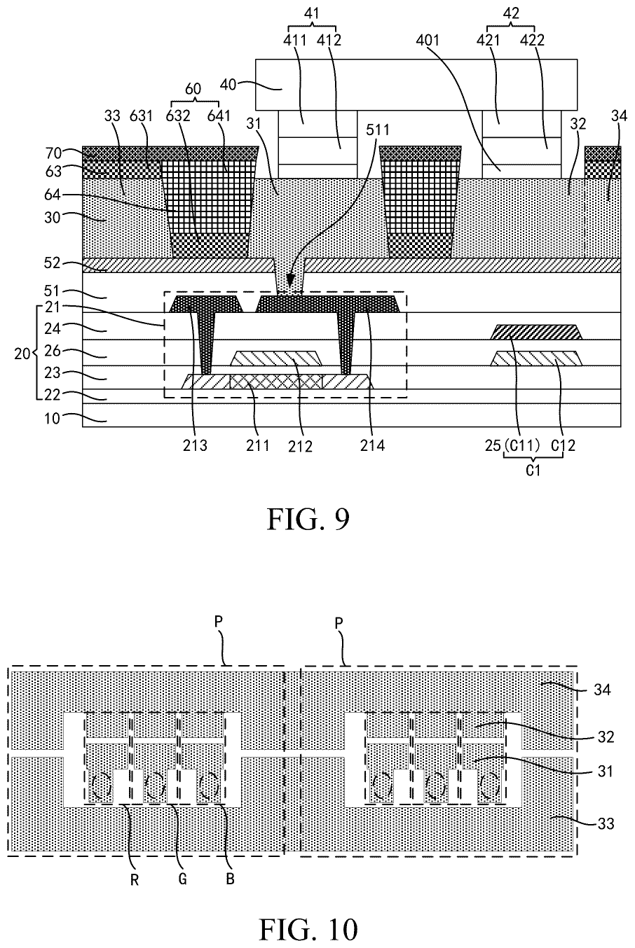

In an embodiment, with reference to FIGS. 2 to 9, FIG. 9 is still another partial film layer schematic structural view of the display panel 100 provided by the embodiment of the present application. With reference to FIG. 9, different from the above embodiment, the display panel 100 further comprises a first planarization layer 51 disposed between the driver circuit layer 20 and the resistance reduction layer 30. The first electrode 31 is connected to the transistor 21 through a first via hole 511 in the first planarization layer 51. Namely, in the present embodiment, the first electrode 31 is directly connected to the drain electrode 214 of the transistor 21 so disposing the first metal layer M1 is not needed, which further lowers a contact resistance of the first electrode 31 to further improve the brightness uniformity. In some other embodiments, the first passivation layer 52 can also be removed. For other descriptions please refer to the above embodiment, and no repeated description is here.

In an embodiment, to improved the film thickness uniformity of the resistance reduction layer 30, the resistance reduction patterns in an electroplating resistance reduction region of the display panel 100 needs to be arranged compactly with a uniform density. In particular, with reference to FIGS. 2 to 10, FIG. 10 is a schematic view of an arrangement of resistance reduction patterns in adjacent two of the display pixels P provided by the embodiment of the present application. With reference to FIGS. 2 and 10, the display panel 100 comprises a display region AA and a frame region BA located outside the display region AA. The display panel 100 further comprises a plurality of display pixels P arranged in an array in the display region AA. An interval between any adjacent two of the display pixels P is the same. Each of the display pixels P comprises at least three subpixels. Each of the subpixels comprises at least one of the transistors 21, one of the first electrodes 31, one of the second electrodes 32, and one of the light emitting devices 40. Each of the display pixels P further comprises a portion of the first power line 33 and a portion of the second power line 34. In each of the display pixels P, a first notch is defined in a side of the first power line 33 near the second power line 34. The first electrode 31 is located in the first notch. A second notch is defined in a side of the second power line 34 near the first power line 33. The second electrode 32 is located in the second notch. In adjacent two of the display pixels P, a difference between area ratios of the resistance reduction patterns is less than 20%. In each of the display pixels P, an area of the resistance reduction patterns refers to a sum of areas of three first electrodes 31, three second electrodes 32, a portion of the first power line 33, and a portion of the second power line 34. In the display panel 100, the resistance reduction pattern in each of the display pixels P is a repeated unit. For other descriptions please refer to the above embodiment, and no repeated description is here.

In an embodiment, with reference to FIG. 2, the frame region BA comprises at least one bonding region PA, the resistance reduction pattern further comprises a bonding terminal BP and/or a fanout wiring located in the bonding region PA. In a unit area of the bonding region PA, a difference between an area ratio of the resistance reduction pattern and an area ratio of the resistance reduction pattern of each of the display pixels P is less than 20%. For other descriptions please refer to the above embodiment, and no repeated description is here.

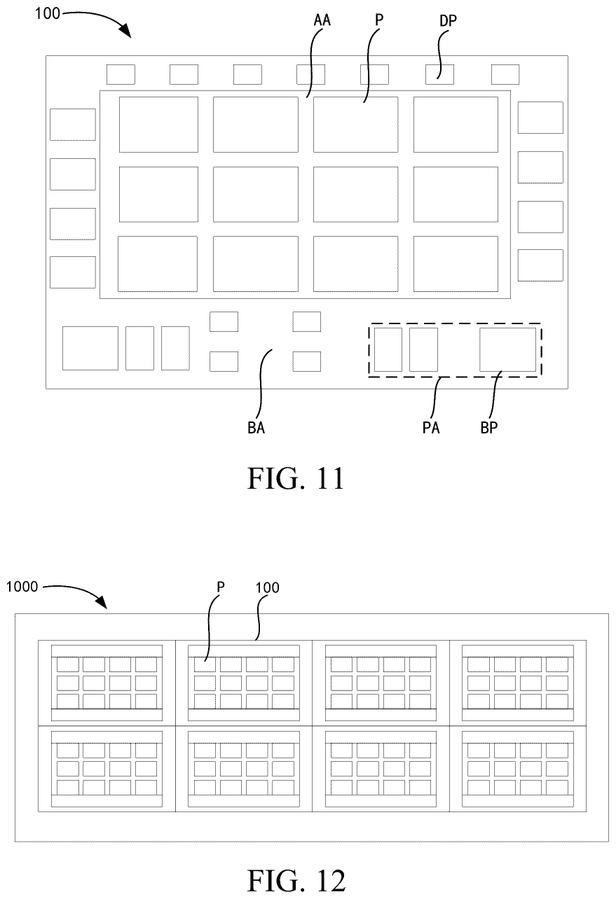

In an embodiment, with reference to FIGS. 2 to 11, FIG. 11 is another plane schematic structural view of the display panel 100 provided by the embodiment of the present application. With reference to FIG. 11, the display panel 100 further comprises a plurality of dummy pixels DP located in the frame region BA. A difference between an area ratio of the resistance reduction pattern in the dummy pixel DP and an area ratio of the resistance reduction pattern in the display pixel P is less than 20%. For other descriptions please refer to the above embodiment, and no repeated description is here.

Based on the same inventive concept, the embodiment of the present application further provides a motherboard 1000. With reference to FIGS. 2 to 12, FIG. 12 is a plane schematic structural view of a motherboard 1000 provided by the embodiment of the present application. With reference to FIG. 12, motherboard 1000 comprises a plurality of display panels 100 arranged in an array, and an interval between adjacent ones of the display panels 100 is the same. The display panel 100 comprises the display panel 100 of one of the above embodiments.

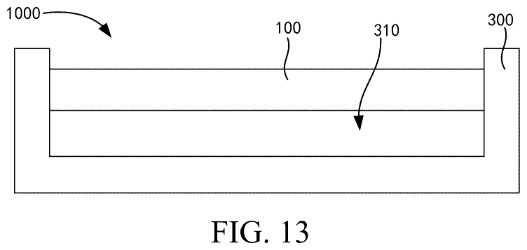

Based on the same inventive concept, the embodiment of the present application also provides a display device, with reference to FIGS. 1 to 13, FIG. 13 is a cross-sectional schematic structural view of the display device provided by the embodiment of the present application. The display device comprises a casing 300 and the display panel 100 of one of the above embodiments. An accommodation cavity 310 is formed in the casing 300, and the display panel 100 is disposed in the accommodation cavity 310.

According to the above embodiment:

The present application provides a display panel, a motherboard and a display device. The display panel comprises an underlay substrate and a driver circuit layer, a resistance reduction layer, and a light emitting device that are sequentially disposed on the underlay substrate. The driver circuit layer comprises a plurality of transistors. A plurality of resistance reduction patterns are formed on the resistance reduction layer. The resistance reduction pattern comprises a first electrode, a second electrode, and a first power line. The first electrode and the first power line are electrically connected to the transistors. The light emitting device comprises a first electrode and a second electrode. The first electrode is bonded to the first electrode, and the second electrode is bonded to the second electrode. A voltage uniformity of the first power line is greater than 85%. The present application forms the first electrode, second electrode, and first power line by using a resistance reduction layer, which can reduce the voltage drop of the first power line, making the voltage uniformity on the first power line greater than 85%. Additionally, the first electrode and second electrode formed by the resistance reduction layer serve as bonding electrodes that can be directly bonded to the electrodes of light emitting devices, without the need for an adhesion layer used to increase the adhesion of the upper and lower film layers between the bonding electrode and the light emitting devices' electrodes. This simplifies the film layer structure of the bonding electrode and the process.

In the above-mentioned embodiments, the descriptions of the various embodiments are focused. For the details of the embodiments not described, reference may be made to the related descriptions of the other embodiments.

The embodiment of the present application are described in detail as above. The principles and implementations of the present application are described in the following by using specific examples. The description of the above embodiments is only for assisting understanding of the technical solutions of the present application and the core ideas thereof. Those of ordinary skill in the art should understand that they can still modify the technical solutions described in the foregoing embodiments or equivalently replace some of the technical features. These modifications or replacements do not make the essence of the technical solutions depart from a range of the technical solutions of the embodiments of the present application.

1. A display panel, comprising:
an underlay substrate;
a driver circuit layer disposed on a side of the underlay substrate, wherein the driver circuit layer comprises a plurality of transistors;
a resistance reduction layer disposed on a side of the driver circuit layer away from the underlay substrate, wherein the resistance reduction layer comprises a plurality of resistance reduction patterns, each of the resistance reduction patterns comprises a first electrode, a second electrode, and a first power line, the first electrode and the first power line are electrically connected to the transistors; and
light emitting devices disposed on a side of the resistance reduction layer away from the underlay substrate, wherein each of The light emitting device comprises a first electrode member and a second electrode member, the first electrode member is bonded to the first electrode, and the second electrode member is bonded to the second electrode;
wherein a voltage uniformity on the first power line is greater than 85%.

2. The display panel according to claim 1, wherein the resistance reduction pattern further comprises a second power line disposed opposite to and spaced from the first power line, a voltage uniformity of the second power line is greater than 85%, and the second power line and the second electrode are disposed integrally.

3. The display panel according to claim 2, wherein material of the resistance reduction layer comprises copper, and a thickness of the resistance reduction layer range ranges from 2 microns to 15 microns.

4. The display panel according to claim 3, wherein the resistance reduction layer comprises a first copper layer and a second copper layer, the second copper layer is located on a side of the first copper layer away from the driver circuit layer, and a thickness of the second copper layer is greater than a thickness of the first copper layer.

5. The display panel according to claim 4, wherein a boundary of the second copper layer extends beyond a boundary of the first copper layer.

6. The display panel according to claim 1, wherein the display panel further comprises a first planarization layer located between the driver circuit layer and the resistance reduction layer; and
wherein a first via hole is defined in the first planarization layer, and the first electrode is connected to the transistor through the first via hole.

7. The display panel according to claim 1, wherein the display panel further comprises:
a first planarization layer disposed between the driver circuit layer and the resistance reduction layer;
a first metal layer disposed on a side of the first planarization layer away from the resistance reduction layer, wherein the first metal layer comprises an auxiliary electrode, and the first electrode is connected to the auxiliary electrode through a second via hole in the first planarization layer; and
a second planarization layer disposed on a side of the first metal layer away from the resistance reduction layer, wherein the auxiliary electrode is connected to the transistor through a third via hole in the second planarization layer.

8. The display panel according to claim 1, wherein the display panel further comprises a soldering layer, the first electrode member and the second electrode member are bonded to the first electrode and the second electrode respectively through corresponding portions of the soldering layer, and the first electrode and the second electrode contact the soldering layer.

9. The display panel according to claim 2, wherein a first gap is formed between adjacent ones of the resistance reduction patterns, the display panel further comprises a filling structure disposed in the first gap, and along a direction perpendicular to the underlay substrate, an absolute value of a difference between a thickness of the filling structure and a thickness of the resistance reduction pattern is less than or equal to 1.5 microns.

10. The display panel according to claim 9, wherein the display panel further comprises:
a first filling layer comprising a first filling portion disposed in the first gap; and
a first anti-reflective layer disposed on a side of the resistance reduction layer away from the driver circuit layer, wherein apertures are formed in portions of the first anti-reflective layer corresponding to the first electrode and the second electrode;
wherein the first anti-reflective layer comprises a first anti-reflective portion covering the resistance reduction patterns and a second anti-reflective portion covering the first filling portion, and the second anti-reflective portion and the first filling portion commonly constitute the filling structure.

11. The display panel according to claim 9, wherein the display panel further comprises:
a second anti-reflective layer, wherein apertures are defined in portions of the second anti-reflective layer corresponding to the first electrode and the second electrode, the second anti-reflective layer comprises a third anti-reflective portion and a fourth anti-reflective portion, the third anti-reflective portion covers the resistance reduction patterns, and the fourth anti-reflective portion is located in the first gap; and
a second filling layer comprising a second filling portion disposed in the first gap, wherein the second filling portion covers the fourth anti-reflective portion, and the fourth anti-reflective portion and the second filling portion commonly constitute the filling structure.

12. The display panel according to claim 9, wherein the display panel further comprises:
a second anti-reflective layer, wherein aperture are defined in portions of second anti-reflective layer corresponding to the first electrode and the second electrode, the second anti-reflective layer comprises a third anti-reflective portion and a fourth anti-reflective portion, the third anti-reflective portion covers the resistance reduction patterns, and the fourth anti-reflective portion is located in the first gap; and
a third anti-reflective layer comprising a fifth anti-reflective portion disposed in the first gap, wherein the fifth anti-reflective portion covers the fourth anti-reflective portion, and the fourth anti-reflective portion and the fifth anti-reflective portion commonly constitute the filling structure.

13. The display panel according to claim 9, wherein the filling structure comprises a protrusion portion, the protrusion portion protrudes from a plane in which a top surface of the resistance reduction pattern is located; an included angle between a side surface of the protrusion portion near the first electrode and a top surface of the first electrode is less than 90 degrees; and/or, an included angle between a side surface of the protrusion portion near the second electrode and a top surface of the second electrode is less than 90 degrees.

14. The display panel according to claim 9, wherein the display panel comprises a display region and a frame region located outside the display region, the display panel further comprises a plurality of display pixels arranged in an array in the display region, an interval between any adjacent two of the display pixels is the same, each of the display pixels comprises at least three subpixels, each of the subpixels comprises at least one of the transistors, and one of the first electrodes, one of the second electrodes, and one of the light emitting devices; and in adjacent two of the display pixels, a difference between area ratios of the resistance reduction patterns is less than 20%.

15. The display panel according to claim 14, wherein the frame region comprises at least one bonding region, the resistance reduction pattern further comprises a bonding terminal and/or a fanout wiring located in the bonding region, and a difference between the area ratio of the resistance reduction pattern in a unit area of the bonding region and the area ratio of the resistance reduction pattern in each of the display pixels is less than 20%.

16. The display panel according to claim 15, wherein the display panel further comprises a plurality of dummy pixels located in the frame region, and a difference between the area ratio of the resistance reduction pattern in the dummy pixels and the area ratio of the resistance reduction pattern in the display pixels is less than 20%.

17. The display panel according to claim 14, wherein each of the display pixels further comprises a portion of the first power line and a portion of the second power line, in each of the display pixels, a first notch is defined in a side of the first power line near the second power line, the first electrode is located in the first notch, a second notch is defined in a side of the second power line near the first power line, and the second electrode is located in the second notch.

18. A display device, comprising a display panel, and the display panel comprising:
an underlay substrate;
a driver circuit layer disposed on a side of the underlay substrate, wherein the driver circuit layer comprises a plurality of transistors;
a resistance reduction layer disposed on a side of the driver circuit layer away from the underlay substrate, wherein the resistance reduction layer comprises a plurality of resistance reduction patterns, each of the resistance reduction patterns comprises a first electrode, a second electrode, and a first power line, the first electrode and the first power line are electrically connected to the transistors; and
light emitting devices disposed on a side of the resistance reduction layer away from the underlay substrate, wherein each of The light emitting device comprises a first electrode member and a second electrode member, the first electrode member is bonded to the first electrode, and the second electrode member is bonded to the second electrode;
wherein a voltage uniformity on the first power line is greater than 85%.

19. The display device according to claim 18, wherein the resistance reduction pattern further comprises a second power line disposed opposite to and spaced from the first power line, a voltage uniformity of the second power line is greater than 85%, and the second power line and the second electrode are disposed integrally.

20. A display panel, comprising:
an underlay substrate;
a driver circuit layer disposed on a side of the underlay substrate, wherein the driver circuit layer comprises a plurality of transistors;
a resistance reduction layer disposed on a side of the driver circuit layer away from the underlay substrate, wherein the resistance reduction layer comprises a plurality of resistance reduction patterns, each of the resistance reduction patterns comprises a first electrode, a second electrode, and a first power line, the first electrode and the first power line are electrically connected to the transistors; and
light emitting devices disposed on a side of the resistance reduction layer away from the underlay substrate, wherein each of The light emitting device comprises a first electrode member and a second electrode member, the first electrode member is bonded to the first electrode, and the second electrode member is bonded to the second electrode;
wherein a voltage uniformity on the first power line is greater than 85%;
wherein the resistance reduction pattern further comprises a second power line disposed opposite to and spaced from the first power line, a voltage uniformity of the second power line is greater than 85%, and the second power line and the second electrode are disposed integrally;
wherein the display panel further comprises:
a first planarization layer disposed between the driver circuit layer and the resistance reduction layer;
a first metal layer disposed on a side of the first planarization layer away from the resistance reduction layer, wherein the first metal layer comprises an auxiliary electrode, and the first electrode is connected to the auxiliary electrode through a second via hole in the first planarization layer; and
a second planarization layer disposed on a side of the first metal layer away from the resistance reduction layer, wherein the auxiliary electrode is connected to the transistor through a third via hole in the second planarization layer.
